(19) United States
(12) Patent Application Publication
(10) Pub. No.: US 2025/0316583 A1
(43) Pub. Date: Oct. 9, 2025

(54) SEMICONDUCTOR DEVICE

(71) Applicant: Samsung Electronics Co., Ltd., Suwon-si (KR)

(72) Inventors: Hoyun JEON, Suwon-si (KR); Kyoung Hee NAM, Suwon-si (KR); Chibeom PARK, Suwon-si (KR); Seungyong YOO, Suwon-si (KR); Eun-Ji JUNG, Suwon-si (KR); Seungkeun CHA, Suwon-si (KR); Taehong HA, Suwon-si (KR)

(73) Assignee: Samsung Electronics Co., Ltd., Suwon-si (KR)

(21) Appl. No.: 19/051,683

(22) Filed: Feb. 12, 2025

(30) Foreign Application Priority Data
Apr. 9, 2024 (KR) 10-2024-0048128

(51) Int. Cl. H01L 23/522; H01L 21/768; H01L 23/528; H01L 23/532

(52) U.S. Cl. CPC H01L 23/5226; H01L 23/5283; H01L 23/53271; H01L 21/76846; H01L 21/76849

(57) ABSTRACT

Example embodiments are directed to a semiconductor device including a conductive structure, and a dielectric layer that surrounds the conductive structure. The conductive structure includes a conductive pattern, a barrier layer in contact with a sidewall and a lower surface of the conductive pattern, a capping layer in contact with an upper surface of the conductive pattern, and a diffusion layer that surrounds the barrier layer and the capping layer. The barrier layer includes a first conductive layer and a second conductive layer that include different conductive materials from each other, the capping layer and the second conductive layer include a same conductive material, the diffusion layer includes manganese (Mn), and the second conductive layer contacts the conductive pattern, the first conductive layer, and the diffusion layer.

### CROSS-REFERENCE TO RELATED APPLICATION

This U.S. nonprovisional application claims priority under 35 U.S.C. § 119 to Korean Patent Application No. 10-2024-0048128 filed on Apr. 9, 2024, in the Korean Intellectual Property Office, the disclosure of which is hereby incorporated by reference in its entirety.

### BACKGROUND

Example embodiments of the inventive concepts relate to a conductive structure of a semiconductor device.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

According to some example embodiments of the inventive concepts, a semiconductor device includes a conductive structure, and a dielectric layer that surrounds the conductive structure. The conductive structure includes a conductive pattern, a barrier layer in contact with a sidewall and a lower surface of the conductive pattern, a capping layer in contact with an upper surface of the conductive pattern, and a diffusion layer that surrounds the barrier layer and the capping layer. The barrier layer includes a first conductive layer and a second conductive layer that include different conductive materials from each other, the capping layer and the second conductive layer include a same conductive material, the diffusion layer includes manganese (Mn), and the second conductive layer contacts the conductive pattern, the first conductive layer, and the diffusion layer.

According to some example embodiments of the inventive concepts, a semiconductor device includes a conductive structure, and a dielectric layer that surrounds the conductive structure. The conductive structure includes a conductive pattern, a barrier layer in contact with a sidewall and a lower surface of the conductive pattern, a capping layer in contact with an upper surface of the conductive pattern, and a diffusion layer that surrounds the barrier layer and the capping layer. The barrier layer includes a plurality of first conductive layers and a plurality of second conductive layers, the first and second conductive layers including different conductive materials from each other, the capping layer and the second conductive layer include a same conductive material, the diffusion layer includes manganese (Mn), and the plurality of first conductive layers and the plurality of second conductive layers are alternately arranged on the sidewall and the lower surface of the conductive pattern.

According to some example embodiments of the inventive concepts, a semiconductor device includes a conductive structure, and a dielectric layer that surrounds the conductive structure. The conductive structure includes a conductive pattern, a barrier layer in contact with a sidewall and a lower surface of the conductive pattern, a capping layer in contact with an upper surface of the conductive pattern, and a diffusion layer that surrounds the barrier layer and the capping layer. The barrier layer includes a first conductive layer and a second conductive layer that include different conductive materials from each other, the capping layer and the second conductive layer include a same conductive material, the diffusion layer includes manganese (Mn), the diffusion layer has a first inner sidewall in contact with a sidewall of the capping layer; and an outer sidewall opposite to the first inner sidewall. A distance between the first inner sidewall and the outer sidewall of the diffusion layer is greater than a thickness of the barrier layer.

### BRIEF DESCRIPTION OF DRAWINGS

For a more complete understanding of this disclosure, reference is now made to the following brief description, taken in connection with the accompanying drawings and detailed description, wherein like reference numerals represent like parts.

FIG. 1A illustrates a cross-sectional view showing a semiconductor device, according to some example embodiments.

FIG. 1B illustrates an enlarged view showing section E1 of FIG. 1A.

FIG. 1C illustrates an enlarged view showing section E2 of FIG. 1A.

FIGS. 2A, 2B, 2C, and 2D illustrate cross-sectional views of the semiconductor device of FIGS. 1A-1C during a method of fabricating the same, according to some example embodiments.

FIG. 2E illustrates an enlarged view showing section E3 of FIG. 2D, according to some example embodiments.

FIG. 3 illustrates a cross-sectional view showing a semiconductor device, according to some example embodiments

FIG. 4 illustrates a cross-sectional view showing a semiconductor device, according to some example embodiments.

FIG. 5A illustrates a plan view showing a semiconductor device, according to some example embodiments.

FIG. 5B illustrates a cross-sectional view taken along line A-A′ of FIG. 5A, according to some example embodiments.

FIG. 5C illustrates a cross-sectional view taken along line B-B′ of FIG. 5A, according to some example embodiments.

FIG. 5D illustrates a cross-sectional view taken along line C-C′ of FIG. 5A, according to some example embodiments.

FIG. 5E illustrates a cross-sectional view taken along line D-D′ of FIG. 5A, according to some example embodiments.

FIG. 5F illustrates an enlarged view showing section F of FIG. 5B, according to some example embodiments.

### DETAILED DESCRIPTION

The size and thickness of each component illustrated in the drawings are arbitrarily shown for understanding and ease of description, but example embodiments are not limited thereto. Thicknesses of several portions and regions are enlarged for clear expressions. In the drawings, the thickness of layers, films, panels, regions, etc., are exaggerated for clarity. In the drawings, for understanding and ease of description, the thickness of some layers and areas is exaggerated.

In addition, unless explicitly described to the contrary, the word “comprise”, and variations such as “comprises” or “comprising”, will be understood to imply the inclusion of stated elements but not the exclusion of any other elements.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

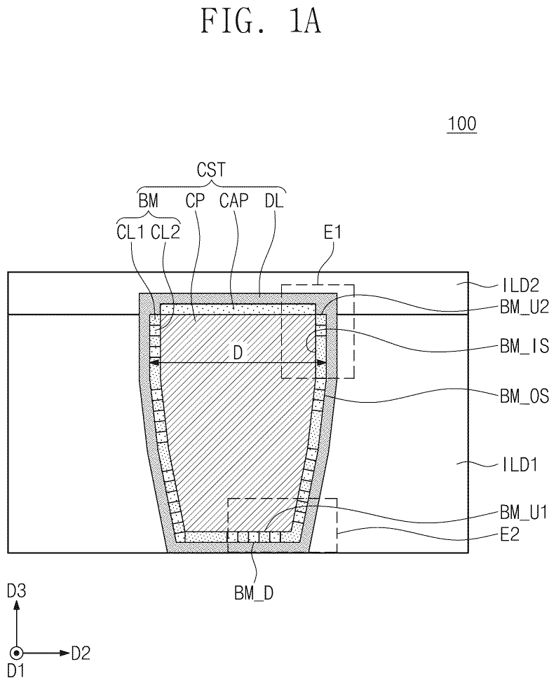

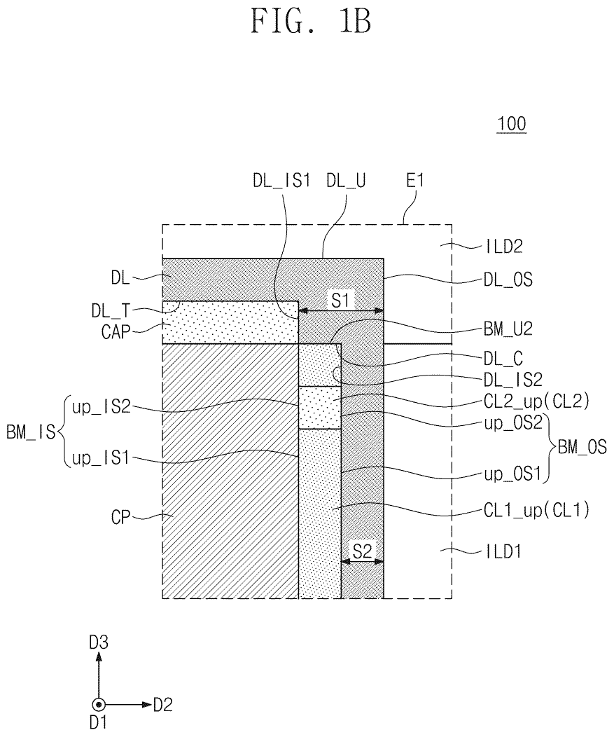

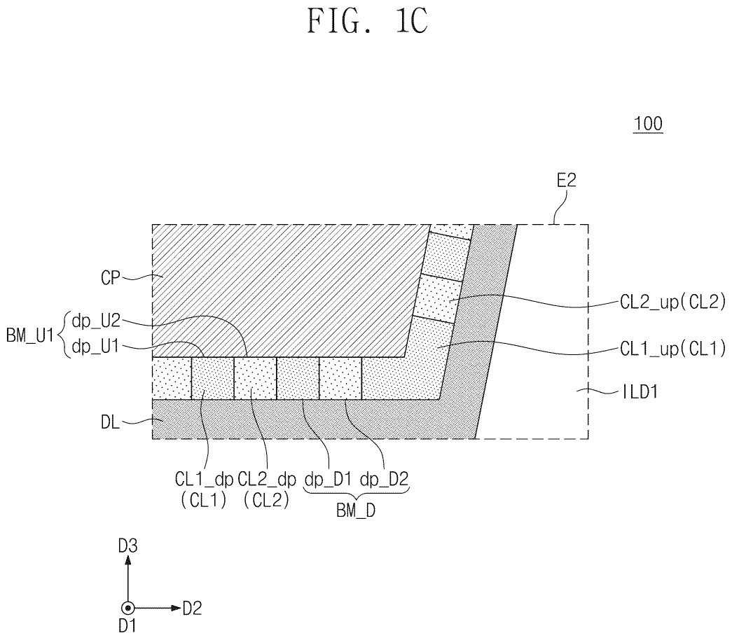

FIG. 1A illustrates a cross-sectional view showing a semiconductor device 100, according to some example embodiments. FIG. 1B illustrates an enlarged view showing section E1 of FIG. 1A. FIG. 1C illustrates an enlarged view showing section E2 of FIG. 1A.

Referring to FIG. 1A, a semiconductor device 100 may include a first dielectric layer ILD1, a second dielectric layer ILD2, and a conductive structure CST. The first dielectric layer ILD1 may extend along a plane defined in a first direction D1 and a second direction D2. The first direction D1 and the second direction D2 may intersect each other. For example, the first direction D1 and the second direction D2 may be horizontal directions and may define a three dimensional (3D) frame of reference along a third direction D3, which may be the vertical direction. The first direction D1, the second direction D2, and the third direction D3 are orthogonal to each other.

The second dielectric layer ILD2 may be formed on the first dielectric layer ILD1. The second dielectric layer ILD2 may be disposed on a top (or upper) surface of the first dielectric layer ILD1.

The first dielectric layer ILD1 and the second dielectric layer ILD2 may be or include a dielectric material. For example, the first dielectric layer ILD1 and the second dielectric layer ILD2 may be or include an oxide.

The conductive structure CST may be formed in the first dielectric layer ILD1 and the second dielectric layer ILD2. The conductive structure CST may be surrounded by the first dielectric layer ILD1 and the second dielectric layer ILD2. As illustrated, a width (in the D2 direction) of a top (or upper) surface of the conductive structure CST may be greater than a width of a bottom (or lower) surface of the conductive structure CST. For example, the conductive structure CST may have a tapered shape whose width decreases in a downward direction, e.g., from the top surface to the bottom surface thereof. The conductive structure CST may include a diffusion layer DL, a barrier layer BM, a conductive pattern CP, and a capping layer CAP.

The diffusion layer DL may be the outermost layer of the conductive structure CST and may be in contact (e.g., direct contact) with the first dielectric layer ILD1 and the second dielectric layer ILD2. The diffusion layer DL may surround the barrier layer BM, the conductive pattern CP, and the capping layer CAP. The diffusion layer DL may have a thickness, for example, ranging from about 2 nm to about 3 nm.

The barrier layer BM may form the sidewalls and the bottom of the conductive structure CST and may contact the diffusion layer DL. The barrier layer BM may be disposed between the conductive pattern CP and the diffusion layer DL. The diffusion layer DL may separate the barrier layer BM from the first dielectric layer ILD1 and the second dielectric layer ILD2. The barrier layer BM may have a thickness, for example, ranging from about 2 nm to about 3 nm.

The barrier layer BM may have an inner sidewall BM_IS, an outer sidewall BM_OS, a first top surface BM_U1, a second top surface BM_U2, and a bottom surface BM_D. The outer sidewall BM_OS and the inner sidewall BM_IS may cooperatively form (or otherwise define) the sidewalls of the conductive structure CST. The outer sidewall BM_OS of the barrier layer BM may be opposite the inner sidewall BM_IS of the barrier layer BM. The bottom surface BM_D of the barrier layer BM may be opposite the first top surface BM_U1 of the barrier layer BM. The second top surface BM_U2 of the barrier layer BM may connect the inner sidewall BM_IS and the outer sidewall BM_OS of the barrier layer BM to each other. The inner sidewall BM_IS and the first top surface BM_U1 of the barrier layer BM may contact (e.g., directly contact) the conductive pattern CP. The outer sidewall BM_OS, the second top surface BM_U2, and the bottom surface BM_D of the barrier layer BM may contact the diffusion layer DL. An entirety of the second top surface BM_U2 of the barrier layer BM may be covered with the diffusion layer DL.

The conductive pattern CP may be formed on the barrier layer BM. The conductive pattern CP may have a bottom surface, sidewalls, and a top surface. The sidewalls of the conductive pattern CP may connect the bottom surface and the top surface of the conductive pattern CP to each other. The sidewall and the bottom surface of the conductive pattern CP may be in contact (e.g., direct contact) with the barrier layer BM. The top surface of the conductive pattern CP may be in contact (e.g., direct contact) with the capping layer CAP. The barrier layer BM and the capping layer CAP may separate the conductive pattern CP from the diffusion layer DL. However, in some example embodiments, at least some portions of the conductive pattern CP may be in contact with the diffusion layer DL. A width (along D2 direction) of conductive pattern CP may increase vertically along the third direction D3.

The capping layer CAP may be provided on the top (or upper) surface of the conductive pattern CP. The capping layer CAP may cover (or overlap) the top (or upper) surface of the conductive pattern CP. The capping layer CAP may be disposed between the conductive pattern CP and the diffusion layer DL. The capping layer CAP may have a thickness (D3 direction), for example, ranging from about 2 nm to about 3 nm.

The capping layer CAP may have a bottom (or lower) surface, a sidewall, and a top surface. The sidewall of the capping layer CAP may connect the bottom surface and the top surface of the capping layer CAP to each other. The bottom surface of the capping layer CAP may be in contact with the upper surface of the conductive pattern CP. The sidewall and the top surface of the capping layer CAP may be in contact with the diffusion layer DL. The capping layer CAP may be or include a conductive material. For example, in some example embodiments, the capping layer CAP may include cobalt (Co).

The barrier layer BM may include first conductive layers CL1 and second conductive layers CL2. The first conductive layers CL1 and the second conductive layers CL2 may be alternately arranged on (or along) the sidewalls and the bottom surface of the conductive pattern CP. The first conductive layer CL1 may be disposed between a pair of neighboring second conductive layers CL2. The second conductive layer CL2 may be disposed between a pair of neighboring first conductive layers CL1.

Referring to FIG. 1B, the diffusion layer DL may have a top surface DL_U, a first inner sidewall DL_IS1, a second inner sidewall DL_IS2, an outer sidewall DL_OS, a contact surface DL_T, and a connection surface DL_C. The top surface DL_U of the diffusion layer DL may be opposite to the contact surface DL_T and the connection surface DL_C of the diffusion layer DL. The outer sidewall DL_OS of the diffusion layer DL may be opposite to the first inner sidewall DL_IS1 and the second inner sidewall DL_IS2 of the diffusion layer DL. The first inner sidewall DL_IS1 of the diffusion layer DL may connect the contact surface DL_T and the connection surface DL_C of the diffusion layer DL to each other. The connection surface DL_C of the diffusion layer DL may connect the first inner sidewall DL_IS1 and the second inner sidewall DL_IS2 of the diffusion layer DL to each other. As illustrated, the contact surface DL_T, the first inner sidewall DL_IS1, the connection surface DL_C, and the second inner sidewall DL_IS2 of the diffusion layer DL may together define or otherwise form an inner surface of the diffusion layer DL. The contact surface DL_T and the connection surface DL_C may generally extend in or along the D2 direction and the first inner sidewall DL_IS1 and the second inner sidewall DL_IS2 may generally extend in or along the D3 direction. The inner surface of the diffusion layer DL may thus have a stepped profile.

The top surface DL_U of the outer sidewall DL_OS of the diffusion layer DL may be in contact with the second dielectric layer ILD2. The outer sidewall DL_OS of the diffusion layer DL may be in contact with the first dielectric layer ILD1. The first inner sidewall DL_IS1 of the diffusion layer DL may be in contact with the sidewall of the capping layer CAP. The second inner sidewall DL_IS2 of the diffusion layer DL may be in contact with the outer sidewall BM_OS of the barrier layer BM. The contact surface DL_T of the diffusion layer DL may be in contact with the top surface of the capping layer CAP. The connection surface DL_C of the diffusion layer DL may be in contact with the second top surface BM_U2 of the barrier layer BM.

Referring to FIG. 1C, the first conductive layers CL1 of the barrier layer BM may include a plurality of first lower conductive layers CL1_dp and a plurality of first upper conductive layers CL1_up. One or more of the plurality of the first upper conductive layers CL1_up may be disposed higher than the plurality of first lower conductive layers CL1_dp. The first lower conductive layers CL1_dp may be in contact with the bottom surface of the conductive pattern CP. In some example embodiments, one or more of the first upper conductive layers CL1_up may be in contact with the sidewall of the conductive pattern CP, the bottom surface of the conductive pattern CP or both the sidewall of the conductive pattern CP and the bottom surface of the conductive pattern CP.

Still referring to FIG. 1C, the second conductive layers CL2 of the barrier layer BM may include a plurality of second lower conductive layers CL2_dp and a plurality of second upper conductive layers CL2_up. One or more of the plurality of the second upper conductive layers CL2_up may be disposed higher than the plurality of second lower conductive layers CL2_dp. The second lower conductive layers CL2_dp may be in contact with the bottom surface of the conductive pattern CP. In some example embodiments, one or more of the second upper conductive layers CL2_up may be in contact with the sidewall of the conductive pattern CP, the bottom surface of the conductive pattern CP or both the sidewall of the conductive pattern CP and the bottom surface of the conductive pattern CP.

The first lower conductive layer CL1_dp may have a bottom surface dp_D1 and a top surface dp_U1, and the second lower conductive layer CL2_dp may have a bottom surface dp_D2 and a top surface dp_U2. The bottom surface dp_D1 of the first lower conductive layer CL1_dp and the bottom surface dp_D2 of the second lower conductive layer CL2_dp may form or otherwise define the bottom surface BM_D of the barrier layer BM. The bottom surface dp_D1 of the first lower conductive layer CL1_dp and the bottom surface dp_D2 of the second lower conductive layer CL2_dp may be in contact with the diffusion layer DL. The bottom surface dp_D1 of the first lower conductive layer CL1_dp may be coplanar with the bottom surface dp_D2 of the second lower conductive layer CL2_dp. The top surface dp_U1 of the first lower conductive layer CL1_dp and the top surface dp_U2 of the second lower conductive layer CL2_dp may form or otherwise define the first top surface BM_U1 of the barrier layer BM. The top surface dp_U1 of the first lower conductive layer CL1_dp and the top surface dp_U2 of the second lower conductive layer CL2_dp may be in contact with the conductive pattern CP. The top surface dp_U1 of the first lower conductive layer CL1_dp may be coplanar with the top surface dp_U2 of the second lower conductive layer CL2_dp.

The first upper conductive layer CL1_up may have an inner sidewall up_IS1 and an outer sidewall up_OS1, and the second upper conductive layer CL2_up may have an inner sidewall up_IS2 and an outer sidewall up_OS2. The inner sidewall up_IS1 of the first upper conductive layer CL1_up and the inner sidewall up_IS2 of the second upper conductive layer CL2_up may form or otherwise define the inner sidewall BM_IS of the barrier layer BM. The inner sidewall up_IS1 of the first upper conductive layer CL1_up and the inner sidewall up_IS2 of the second upper conductive layer CL2_up may be in contact with the conductive pattern CP. The inner sidewall up_IS1 of the first upper conductive layer CL1_up may be coplanar with the inner sidewall up_IS2 of the second upper conductive layer CL2_up. The outer sidewall up_OS1 of the first upper conductive layer CL1_up and the outer sidewall up_OS2 of the second upper conductive layer CL2_up may form or otherwise define the outer sidewall BM_OS of the barrier layer BM. The outer sidewall up_OS1 of the first upper conductive layer CL1_up and the outer sidewall up_OS2 of the second upper conductive layer CL2_up may be in contact with the diffusion layer DL. The outer sidewall up_OS1 of the first upper conductive layer CL1_up may be coplanar with the outer sidewall up_OS2 of the second upper conductive layer CL2_up.

The first conductive layers CL1 of the barrier layer BM may include a plurality of first lower conductive layers CL1_dp. The first lower conductive layers CL1_dp adjacent to each other may be spaced apart from each other horizontally (e.g., in the D2 direction) by one (e.g., a single) second lower conductive layer CL2_dp. The first lower conductive layers CL1_dp adjacent to each other may be in contact with the one second lower conductive layer CL2_dp.

The second conductive layers CL2 of the barrier layer BM may include a plurality of second lower conductive layers CL2_dp. The second lower conductive layers CL2_dp adjacent to each other may be spaced apart from each other horizontally (e.g., in the D2 direction) by one (e.g., a single) first lower conductive layer CL1_dp. The second lower conductive layers CL2_dp adjacent to each other may be in contact with the one first lower conductive layer CL1_dp.

The first conductive layers CL1 of the barrier layer BM may include a plurality of first upper conductive layers CL1_up. The first upper conductive layers CL1_up adjacent to each other may be spaced apart from each other by one (e.g., a single) second upper conductive layer CL2_up. The first upper conductive layers CL1_up adjacent to each other may be in contact with the one second upper conductive layer CL2_up.

The second conductive layers CL2 of the barrier layer BM may include a plurality of second upper conductive layers CL2_up. The second upper conductive layers CL2_up adjacent to each other may be spaced apart from each other by one (e.g., a single) first upper conductive layer CL1_up. The second upper conductive layers CL2_up adjacent to each other may be in contact with the one first upper conductive layer CL1_up. In some example embodiments, the widths (D2 direction) of the first conductive layers CL1 (e.g., first lower conductive layers CL1_dp) and the second conductive layers CL2 (e.g., second lower conductive layers CL2_dp) may be different. In some example embodiments, the heights (D3 direction) of the first conductive layers CL1 (e.g., first upper conductive layers CL1_up) and the second conductive layers CL2 (e.g., second upper conductive layers CL2_up) may be different.

Referring to FIG. 1B, the top surface DL_U of the diffusion layer DL may be at a level higher than that of the top surface of the capping layer CAP. The contact surface DL_T of the diffusion layer DL may be at a level higher than that of the second top surface BM_U2 of the barrier layer BM. The top surface of the conductive pattern CP may be coplanar with the second top surface BM_U2 of the barrier layer BM.

A width (in the D2 direction) of the top surface DL_U of the diffusion layer DL may be greater than a diameter D (in the D2 direction) of the outer sidewall BM_OS of the barrier layer BM. The width of the top surface DL_U of the diffusion layer DL may be greater than a width (in the D2 direction) of the capping layer CAP. A width of the top surface of the conductive pattern CP may be the same or nearly the same (e.g., within +/−1%-2%) as the width of the capping layer CAP.

A distance S1 between the first inner sidewall DL_IS1 and the outer sidewall DL_OS of the diffusion layer DL may be greater than a distance S2 between the second inner sidewall DL_IS2 and the outer sidewall DL_OS of the diffusion layer DL. The distance S1 between the first inner sidewall DL_IS1 and the outer sidewall DL_OS of the diffusion layer DL may be, for example, a minimum distance between the first inner sidewall DL_IS1 and the outer sidewall DL_OS of the diffusion layer DL. The distance S2 between the second inner sidewall DL_IS2 and the outer sidewall DL_OS of the diffusion layer may be, for example, a minimum distance between the second inner sidewall DL_IS2 and the outer sidewall DL_OS of the diffusion layer DL.

The distance S1 between the first inner sidewall DL_IS1 and the outer sidewall DL_OS of the diffusion layer DL may be greater than the thickness of the barrier layer BM.

The diffusion layer DL may be or include a conductive material. For example, in some example embodiments the diffusion layer DL may include manganese (Mn). In some other example embodiments, the diffusion layer DL may include, for example, manganese oxide (MnO).

The conductive pattern CP may be or include a conductive material. For example, in some example embodiments, the conductive pattern CP may be or include copper (Cu). In some other example embodiments, the conductive pattern CP may be or include at least one selected from copper (Cu) and manganese (Mn).

The first conductive layer CL1 and the second conductive layer CL2 may include different conductive materials from each other. The second conductive layer CL2 may include the same conductive material as that of the capping layer CAP. For example, in some example embodiments, the first conductive layer CL1 may include TaN, and the second conductive layer CL2 and the capping layer CAP may include cobalt (Co).

A concentration (or content, or amount) of manganese (Mn) in the diffusion layer DL may be higher than a concentration (or content, or amount) of manganese (Mn) in the first conductive layer CL1, a concentration (or content, or amount) of manganese (Mn) in the second conductive layer CL2, and a concentration (or content, or amount) of manganese (Mn) in the capping layer CAP. The concentration (or content, or amount) of manganese (Mn) in the diffusion layer DL may be higher than a concentration (or content, or amount) of manganese (Mn) in the conductive pattern CP. A concentration (or content, or amount) of cobalt (Co) in the second conductive layer CL2 may be higher than a concentration (or content, or amount) of cobalt (Co) in the conductive pattern CP and a concentration (or content, or amount) of cobalt (Co) in the first conductive layer CL1.

The semiconductor device, according to some example embodiments, may be configured such that the conductive structure CST includes the diffusion layer DL which surrounds the barrier layer BM and the capping layer CAP. The presence of the diffusion layer DL may reduce, or minimize or limit electromigration (EM) in the conductive structure CST. Accordingly, a reliability of the semiconductor device may be increased or improved.

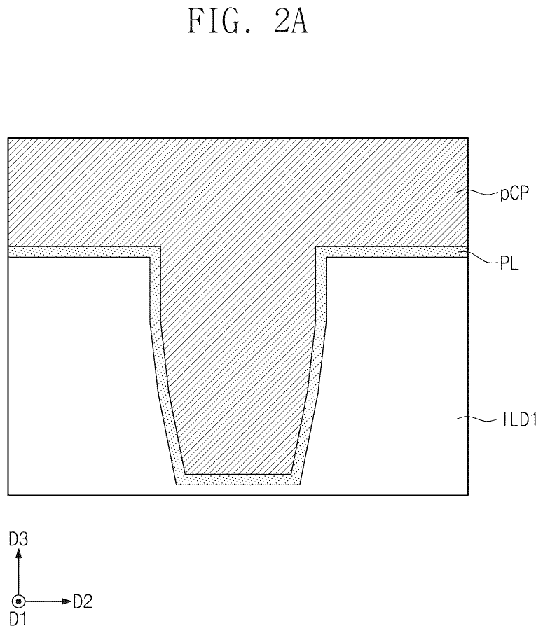

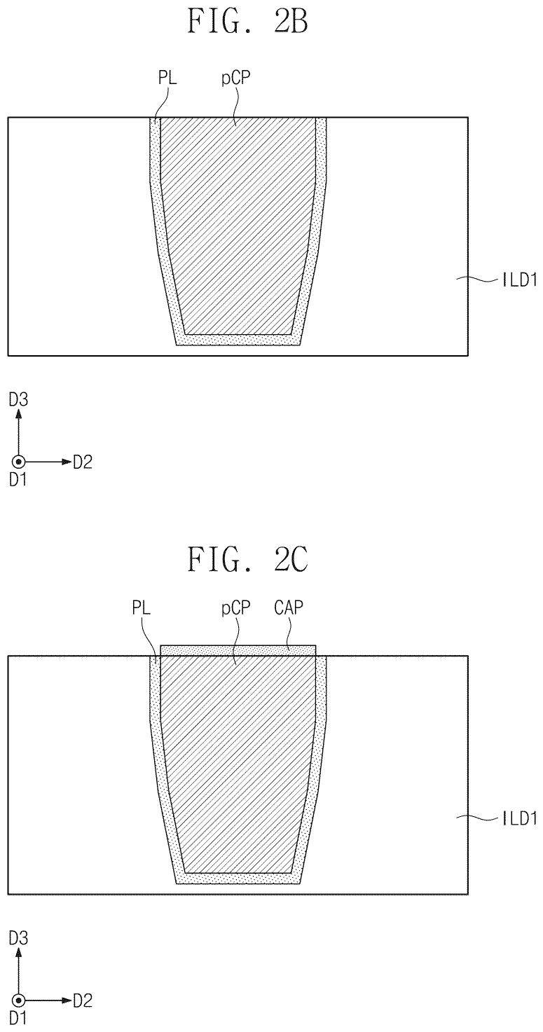

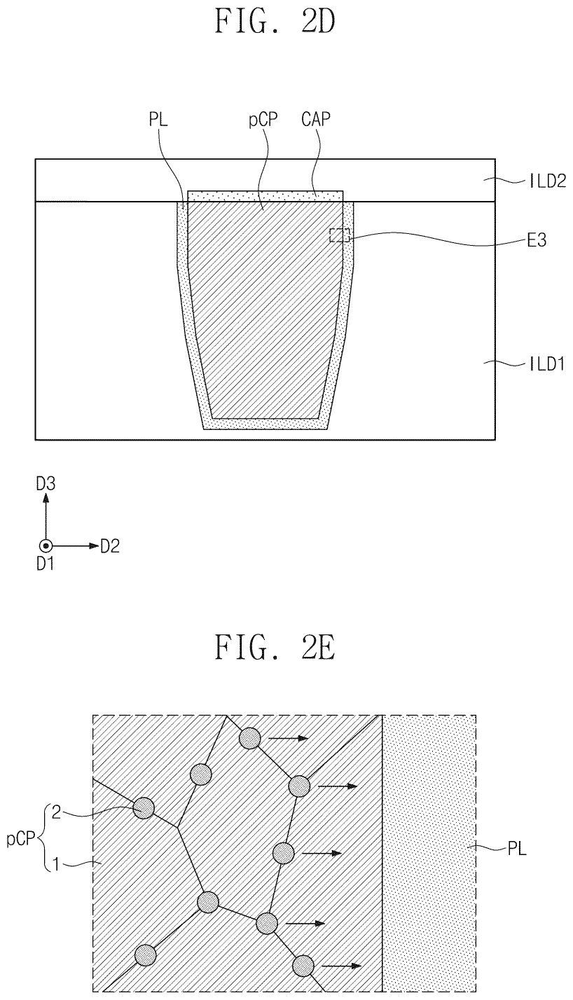

FIGS. 2A, 2B, 2C, and 2D illustrate cross-sectional views of the semiconductor device 100 of FIGS. 1A-1C during a method of fabricating the same, according to some example embodiments. FIG. 2E illustrates an enlarged view showing section E3 of FIG. 2D.

Referring to FIG. 2A, a first dielectric layer ILD1 may be formed on a semiconductor substrate. The first dielectric layer ILD1 may be etched to form an opening. A preliminary barrier layer PL may be formed in the opening of the first dielectric layer ILD1 and on an upper surface of the first dielectric layer ILD1. The preliminary barrier layer PL may conformally cover the first dielectric layer ILD1. The preliminary barrier layer PL may be or include a conductive material. For example, the preliminary barrier layer PL may include TaN. In some other example embodiments, the preliminary barrier layer PL may be formed using an atomic layer deposition (ALD) process.

A preliminary conductive pattern pCP may be formed on the preliminary barrier layer PL located in the opening and on the upper surface of the first dielectric layer ILD1. The preliminary conductive pattern pCP may cover the preliminary barrier layer PL in the opening and on the upper surface of the first dielectric layer ILD1. The preliminary conductive pattern pCP may be or include a conductive material. For example, the preliminary conductive pattern pCP may include copper manganese (CuMn). An amount of manganese (Mn) in the preliminary conductive pattern pCP may range, for example, from about 0.5 wt % to about 15 wt %.

Referring to FIG. 2B, a removal action may be performed on an upper portion of the preliminary barrier layer PL and an upper portion of the preliminary conductive pattern pCP. An upper portion of each of the preliminary barrier layer PL and the preliminary conductive pattern pCP may be removed to expose a top surface of the first dielectric layer ILD1 while retaining at least a portion of the preliminary barrier layer PL and the preliminary conductive pattern pCP in the opening. In some example embodiments, a chemical mechanical polishing (CMP) process may be used to remove an upper portion of the preliminary barrier layer PL and an upper portion of the preliminary conductive pattern pCP. The removal action may result in the top surface of the first dielectric layer ILD1 that may be coplanar with a top surface of the preliminary barrier layer PL and a top surface of the preliminary conductive pattern pCP.

Referring to FIG. 2C, a capping layer CAP may be formed on the preliminary conductive pattern pCP. The capping layer CAP may cover the top surface of the preliminary conductive pattern pCP, while the upper surface of the preliminary barrier layer PL may remain exposed. A bottom surface of the capping layer CAP may be in contact with the top surface of the preliminary conductive pattern pCP. The formation of the capping layer CAP may conceal or cover (e.g., entirely) the preliminary conductive pattern pCP. The preliminary conductive pattern pCP may be surrounded by the preliminary barrier layer PL and the capping layer CAP. In some example embodiments, the capping layer CAP may be formed using a chemical vapor deposition (CVD) process.

Referring to FIG. 2D, a second dielectric layer ILD2 may be formed. The second dielectric layer ILD2 may cover the top surface of the first dielectric layer ILD1, the top surface of the preliminary barrier layer PL, and a top surface of the capping layer CAP. The second dielectric layer ILD2 may be in contact (e.g., in direct contact) with the top surface of the first dielectric layer ILD1, the top surface of the preliminary barrier layer PL, and the top surface of the capping layer CAP.

Referring to FIG. 2E, the preliminary conductive pattern pCP may include crystals 1 and particles 2. For example, the crystal 1 may include copper (Cu), and the particle 2 may include manganese (Mn). The particles 2 may be disposed (or embedded) between the crystals 1. For example, the particles 2 may be disposed between grain boundaries of the crystals 1. Sizes of the crystals 1 may increase due to heat applied to a semiconductor device during fabrication process, and this may cause the particles 2 between the crystals 1 to move toward the preliminary layer PL.

Heat applied to a semiconductor device during fabrication process may cause some of the material of the capping layer CAP to move between the grain boundaries in the preliminary barrier layer PL. The material of the capping layer CAP that moves into the preliminary barrier layer PL may form the second conductive layers CL2 (FIG. 1A). The second conductive layers CL2 in the preliminary barrier layer PL may be formed in multiple, discrete locations within the preliminary barrier layer PL and, as result, the preliminary barrier layer PL may include a plurality of the second conductive layers CL2 and a plurality of first conductive layers CL1. Thus, a barrier layer BM having a plurality of first conductive layers CL1 and a plurality of the second conductive layers CL2 may be formed.

The particles 2 of the preliminary conductive pattern pCP may move to form a diffusion layer DL. Heat applied to a semiconductor device during fabrication process may force the particles 2 of the preliminary conductive pattern pCP to move out of the preliminary conductive pattern pCP. The particles 2 may pass through the barrier layer BM and the capping layer CAP. The particles 2, which have passed through the barrier layer BM and the capping layer CAP, may surround the barrier layer BM and the capping layer CAP. A diffusion layer DL including the particles 2 that surround the barrier layer BM and the capping layer CAP may thus be defined or formed. The formation of the diffusion layer DL and the barrier layer BM may define the conductive structure CST.

In a method of fabricating a semiconductor device according to some example embodiments, as the capping layer CAP is not present between the barrier layer BM and the conductive pattern CP, undulation on a top (or upper) surface of the conductive pattern CP, for instance, after a chemical mechanical polishing (CMP) operation may be reduced or minimized. Therefore, the conductive structure CST having a reduced volume and resistance may be obtained, and electrical properties of the semiconductor device may be improved.

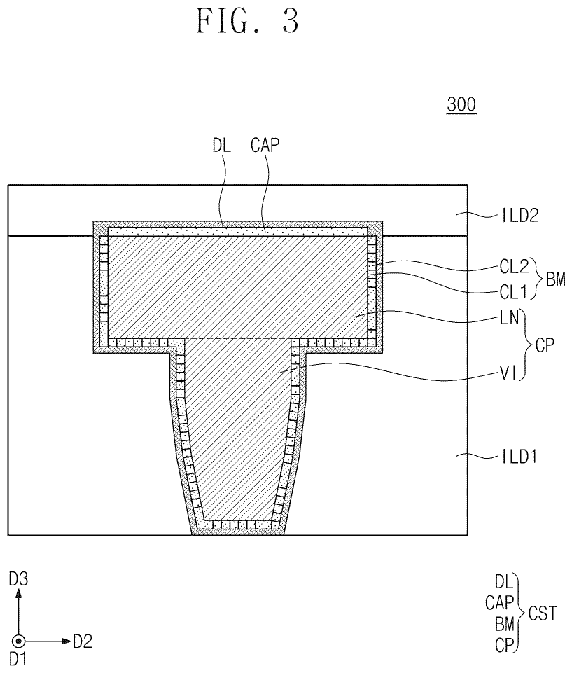

FIG. 3 illustrates a cross-sectional view showing a semiconductor device 300, according to some example embodiments. The semiconductor device 300 may be similar in some respects to the semiconductor device 100 of FIGS. 1A-1C, and therefore may be best understood with reference thereto where like numerals indicate like elements not described again in detail.

Referring to FIG. 3, the conductive pattern CP may include a via part VI and a wiring part LN on the via part VI. The wiring part LN of the conductive pattern CP may be located on or over (in the D3 direction) the via part VI of the conductive pattern CP. The wiring part LN of the conductive pattern CP may be disposed between the capping layer CAP and the via part VI of the conductive pattern CP. The wiring part LN of the conductive pattern CP may have a width (D2 direction) greater than that of the via part VI of the conductive pattern CP.

The via part VI of the conductive pattern CP may be separated (D3 direction) from the capping layer CAP by the wiring part LN. The via part VI of the conductive pattern CP may be in contact with the barrier layer BM. The wiring part LN of the conductive pattern CP may be in contact with the capping layer CAP. The wiring part LN of the conductive pattern CP may have a top (or upper) surface in contact with the bottom surface of the capping layer CAP. The wiring part LN of the conductive pattern CP may have a sidewall in contact with the barrier layer BM.

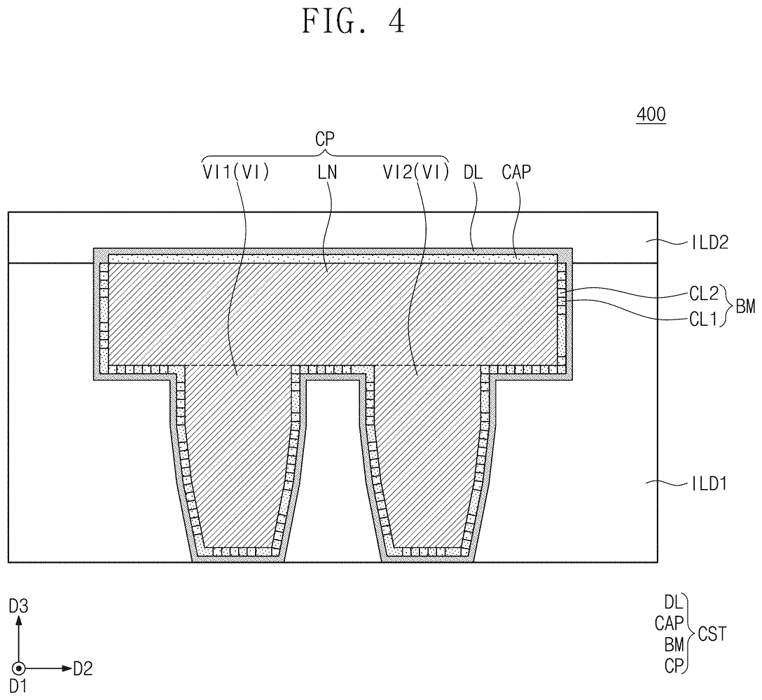

FIG. 4 illustrates a cross-sectional view showing a semiconductor device 400, according to some example embodiments. The semiconductor device 400 may be similar in some respects to the semiconductor devices 100 of FIGS. 1A-1C and the semiconductor device 300 of FIG. 3, and therefore may be best understood with reference thereto where like numerals indicate like elements not described again in detail.

Referring to FIG. 4, the conductive pattern CP may include a first via part VI1, a second via part VI2, and a wiring part LN connected to the first via part VI1 and the second via part VI2. The first via part VI1 and the second via part VI2 may be horizontally (D2 direction) spaced from each other. The first via part VI1 and the second via part VI2 may be vertically spaced from the capping layer CAP. The first via part VI1 and the second via part VI2 may be in contact with the barrier layer BM. The wiring part LN may be disposed on the first via part VI1 and the second via part VI2. The number of the via parts VI1 and VI2 may not be limited two, as illustrated in FIG. 4. For example, in some example embodiments, the semiconductor device 400 may include three or more via parts.

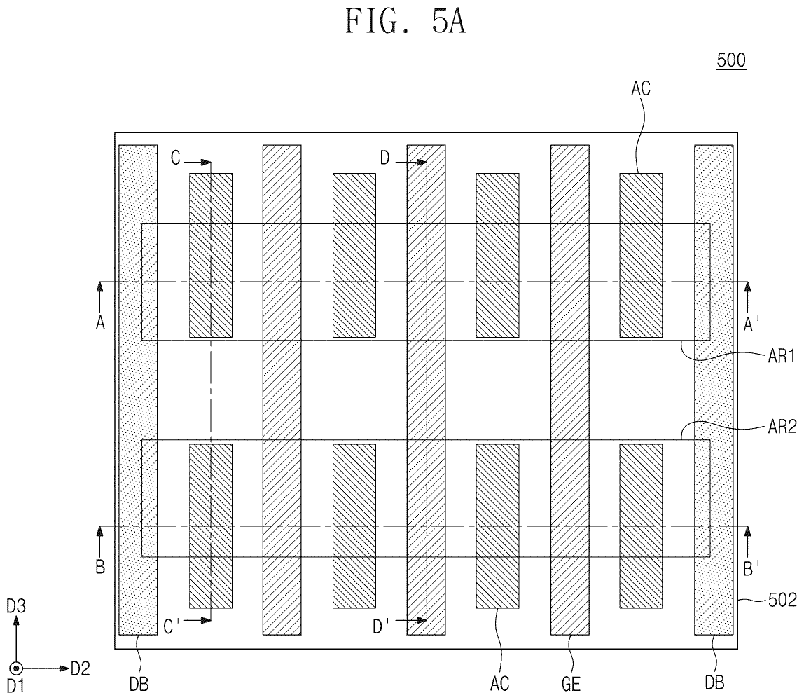

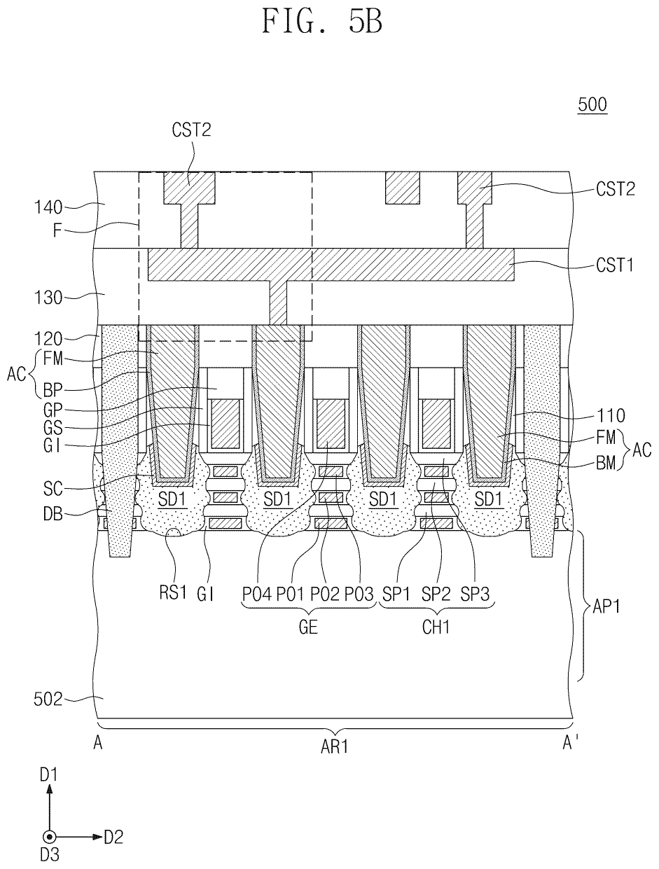

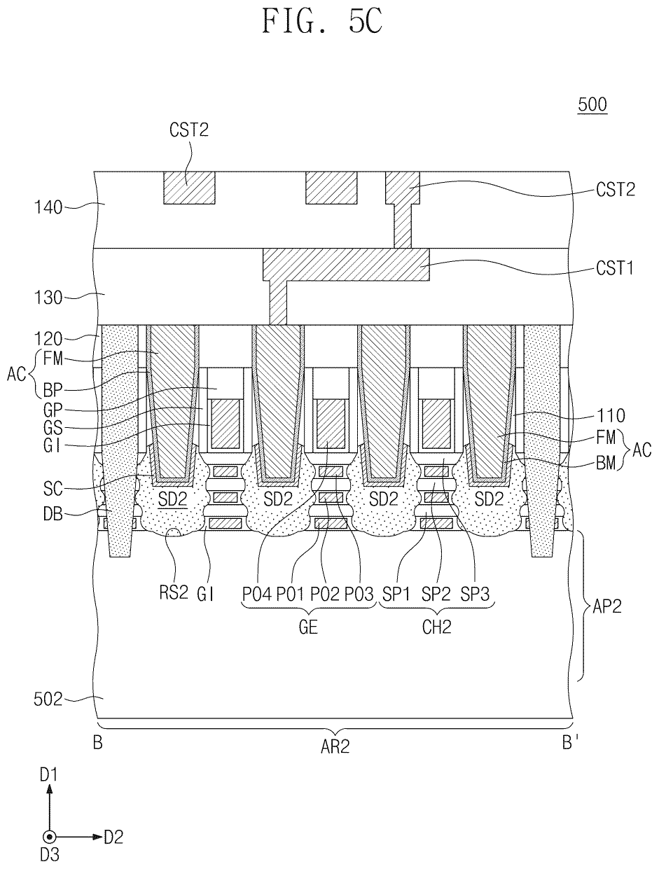

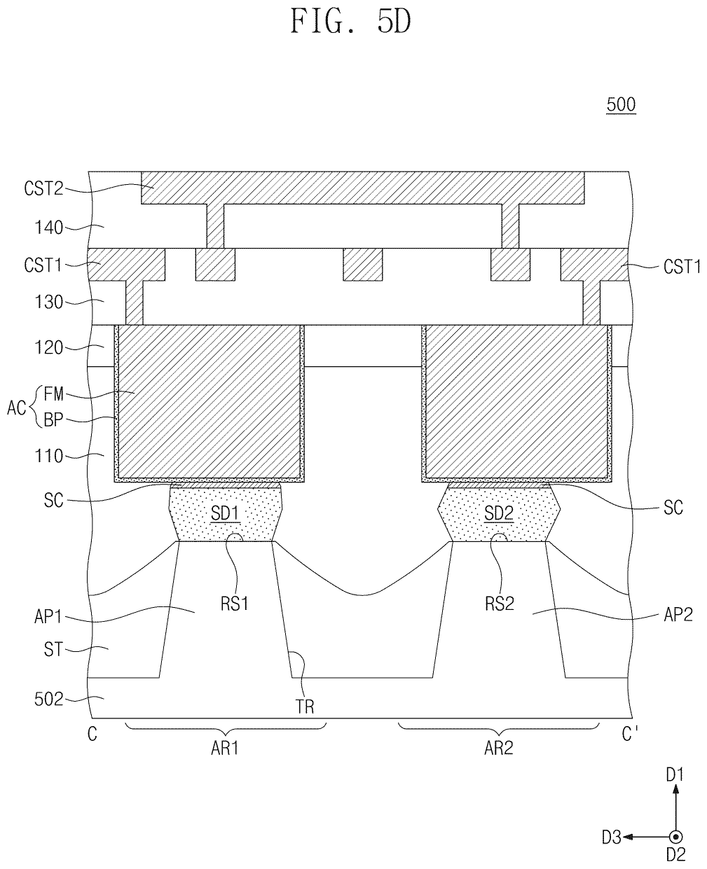

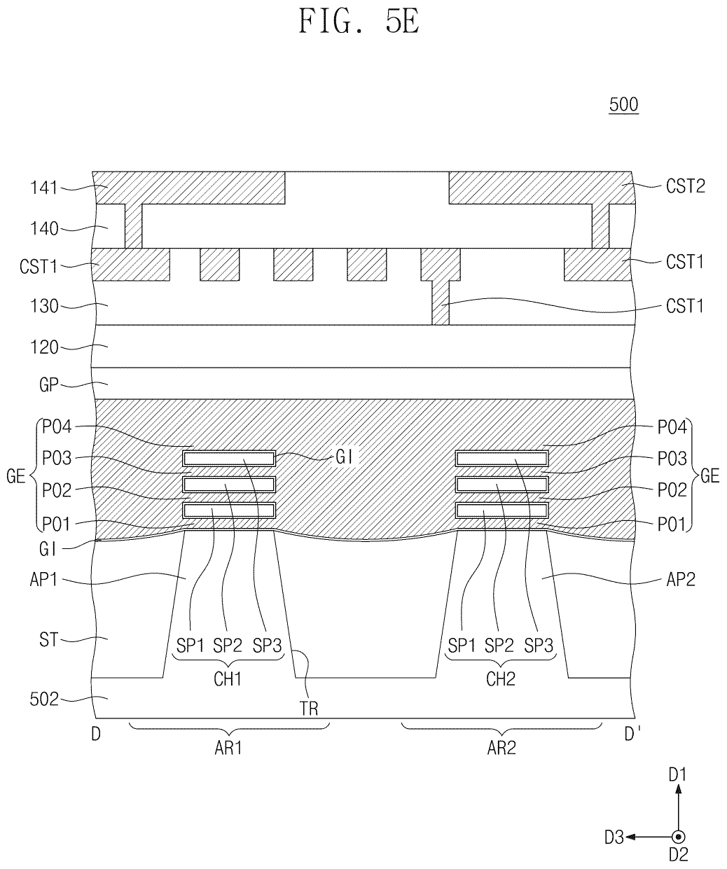

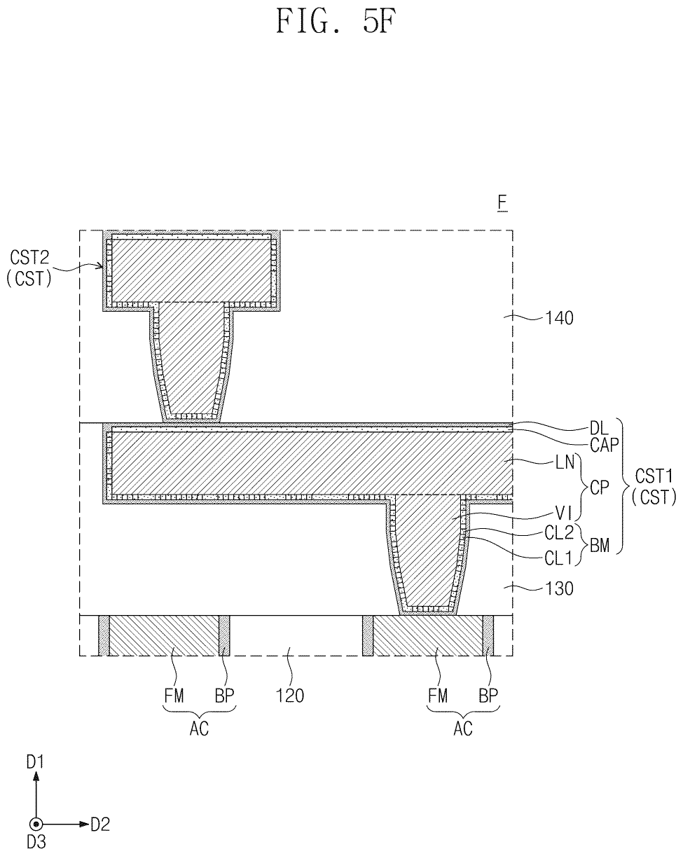

FIG. 5A illustrates a plan view showing a semiconductor device, according to some example embodiments. FIG. 5B illustrates a cross-sectional view taken along line A-A′ of FIG. 5A. FIG. 5C illustrates a cross-sectional view taken along line B-B′ of FIG. 5A. FIG. 5D illustrates a cross-sectional view taken along line C-C′ of FIG. 5A. FIG. 5E illustrates a cross-sectional view taken along line D-D′ of FIG. 5A. FIG. 5F illustrates an enlarged view showing section F of FIG. 5B.

Referring to FIGS. 5A, 5B, 5C, 5D, and 5E, a semiconductor device 500 may include a substrate 502. The substrate 502 may include one or more logic circuits having logic transistors. In some example embodiments, the substrate 502 may be a semiconductor substrate. For example, the substrate 502 may be or include silicon (Si), germanium (Ge), silicon-germanium (SiGe), gallium phosphide (GaP), gallium arsenide (GaAs), combinations thereof, and the like. In some example embodiments, the substrate 502 may be a silicon-on-insulator (SOI) substrate or a germanium-on-insulator (GOI) substrate. The substrate 502 may have a plate shape that extends along a plane elongated in a first direction D1 and a second direction D2.

The substrate 502 may include a first active region AR1 and a second active region AR2. Each of the first and second active regions AR1 and AR2 may extend in the second direction D2. In some example embodiments, the first active region AR1 may be an NMOSFET region, and the second active region AR2 may be a PMOSFET region.

The substrate 502 may include a first active pattern AP1 and a second active pattern AP2. The first active pattern AP1 and the second active pattern AP2 may be defined by a trench TR on the substrate 502. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be portions that protrude in a first direction D1. The third direction D3 may intersect the first direction D1 and the second direction D2. The first direction D1, the second direction D2, and the third direction D3 may be orthogonal to each other.

A device isolation layer ST may be formed on the substrate 502. The device isolation layer ST may fill the trench TR. The device isolation layer ST may include a dielectric material. For example, the device isolation layer ST may include oxide.

The first channel patterns CH1 may be formed on or overlapping the first active pattern AP1. The second channel patterns CH2 may be formed on or overlapping the second active pattern AP2. Each of the first and second channel patterns CH1 and CH2 may include a first semiconductor pattern SP1, a second semiconductor pattern SP2, and a third semiconductor pattern SP3 that are sequentially arranged in the first direction D1. The first, second, and third semiconductor patterns SP1, SP2, and SP3 may be spaced apart from each other in the first direction D1.

In some example embodiments, the first, second, and third semiconductor patterns SP1, SP2, and SP3 may include silicon (Si). For example, each of the first, second, and third semiconductor patterns SP1, SP2, and SP3 may include crystalline silicon. In some example embodiments, the first, second, and third semiconductor patterns SP1, SP2, and SP3 may include silicon-germanium (SiGe).

A plurality of first source/drain patterns SD1 may be formed on the first active pattern AP1. A plurality of first recesses RS1 may be formed on the first active pattern AP1. The first source/drain patterns SD1 may be correspondingly provided in the first recesses RS1. The first channel pattern CH1 may be interposed between neighboring first source/drain patterns SD1. For example, the first, second, and third semiconductor patterns SP1, SP2, and SP3 may connect neighboring first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be correspondingly provided in the second recesses RS2. The second channel pattern CH2 may be interposed between neighboring second source/drain patterns SD2. For example, the first, second, and third semiconductor patterns SP1, SP2, and SP3 arranged in the third direction D3 may connect neighboring second source/drain patterns SD2 to each other.

In some example embodiments, the second source/drain pattern SD2 may include a low-concentration semiconductor layer and a high-concentration semiconductor layer on the low-concentration semiconductor layer. The low-concentration semiconductor layer may be in contact with the first, second, and third semiconductor patterns SP1, SP2, and SP3, and the high-concentration semiconductor layer may be spaced apart from the first, second, and third semiconductor patterns SP1, SP2, and SP3. The low-concentration semiconductor layer and the high-concentration semiconductor layer may include a Group 13 element and a Group 14 element. The low-concentration semiconductor layer and the high-concentration semiconductor layer may include an extrinsic semiconductor material. The low-concentration semiconductor layer and the high-concentration semiconductor layer may include a p-type semiconductor material in which a Group 13 element is doped as an impurity. For example, the low-concentration semiconductor layer and the high-concentration semiconductor layer may include SiGe (e.g., SiGeB, SiGeGa, or SiGeIn) in which B, Ga, or In is doped as an impurity. An impurity concentration of the low-concentration semiconductor layer may be less than an impurity concentration of the high-concentration semiconductor layer.

The first and second source/drain patterns SD1 and SD2 may be epitaxial patterns formed by a selective epitaxial growth (SEG) process. In some example embodiments, each of the first and second source/drain patterns SD1 and SD2 may have a top (or upper) surface higher than that of the third semiconductor pattern SP3. In some example embodiments, each of the first and second source/drain patterns SD1 and SD2 may have a top (or upper) surface lower than that of the third semiconductor pattern SP3. In some example embodiments, each of the first and second source/drain patterns SD1 and SD2 may have a top (or upper) surface at the same level as that of a top (or upper) surface of the third semiconductor pattern SP3.

A plurality of gate electrodes GE may be formed extending in the third direction D3 and transversely across the first and second channel patterns CH1 and CH2. The gate electrodes GE may be arranged at a first pitch in the second direction D2. Each of the gate electrodes GE may overlap in the first direction D1 with the first, second, and third semiconductor patterns SP1, SP2, and SP3 of a corresponding one of the first and second channel patterns CH1 and CH2.

The gate electrode GE may include a first part PO1 interposed between the first semiconductor pattern SP1 and the active pattern AP1 or AP2, a second part PO2 interposed between the first semiconductor pattern SP1 and the second semiconductor pattern SP2, a third part PO3 interposed between the second semiconductor pattern SP2 and the third semiconductor pattern SP3, and a fourth part PO4 on the third semiconductor pattern SP3. The gate electrode GE may include a conductive material.

The gate electrode GE and the first, second, and third semiconductor patterns SP1, SP2, and SP3 three-dimensionally surrounded by the gate electrode GE may constitute a three-dimensional field effect transistor (e.g., MBCFET or GAAFET).

A pair of gate spacers GS may be formed on opposite sidewalls of the gate electrode GE. The gate spacers GS may extend in the third direction D3 along the gate electrode GE. The gate spacers GS may have top (or upper) surfaces higher than that of the gate electrode GE. The top (or upper) surfaces of the gate spacers GS may be coplanar with top (or upper) surfaces of a first interlayer dielectric layer 110.

A gate capping pattern GP may be formed on the gate electrode GE. The gate capping pattern GP may extend in the third direction D3 along the gate electrode GE. The gate capping pattern GP may include a material having an etch selectivity with respect to first and second interlayer dielectric layers 110 and 120. In some example embodiments, the gate capping pattern GP may include nitride.

Each of a plurality of gate dielectric layers GI may separate the gate electrode GE from the first channel pattern CH1 and the second channel pattern CH2. The gate dielectric layer GI may three-dimensionally surround the first, second, and third semiconductor patterns SP1, SP2, and SP3. The gate dielectric layer GI may cover the device isolation layer ST. The gate dielectric layer GI may include a dielectric material. For example, the gate dielectric layer GI may include oxide.

A first interlayer dielectric layer 110 may be formed to cover the gate spacers GS and the first and second source/drain patterns SD1 and SD2. The first interlayer dielectric layer 110 may have a top (or upper) surface coplanar with a top (or upper) surfaces of the gate capping pattern GP and the gate spacer GS. A second interlayer dielectric layer 120 may be formed over the first interlayer dielectric layer 110 and may cover the gate capping pattern GP. A third interlayer dielectric layer 130 may be formed on the second interlayer dielectric layer 120. A fourth interlayer dielectric layer 140 may be formed on the third interlayer dielectric layer 130. The first, second, third, and fourth interlayer dielectric layers 110, 120, 130, and 140 may each include a dielectric material. For example, the first, second, third, and fourth interlayer dielectric layers 110, 120, 130, and 140 may each include an oxide.

A plurality of separation structures DB may extend in the third direction D3. The gate electrodes GE may be disposed between the separation structures DB. A pitch between the separation structure DB and its adjacent gate electrode GE may be the same as the first pitch between the gate electrodes GE arranged in the second direction D2.

The separation structure DB may penetrate the first and second interlayer dielectric layers 110 and 120 and extend into the first and second active patterns AP1 and AP2. A lower portion of the separation structure DB may penetrate in the first direction D1 through an upper portion of each of the first and second active patterns AP1 and AP2.

A plurality of active contacts AC may penetrate the first and second interlayer dielectric layers 110 and 120 and be electrically connected with the first and second source/drain patterns SD1 and SD2. The gate electrode GE may be formed between neighboring active contacts AC. Referring to the plan view in FIG. 5A, the active contact AC may have a bar shape that extends in the third D3. The active contact AC may cover at least a portion of a sidewall of the gate spacer GS.

A metal-semiconductor compound layer SC may be formed in each of the first source/drain pattern SD1 and the second source/drain pattern SD2. Each metal-semiconductor compound layer SC may be interposed between the active contact AC and the first source/drain pattern SD1 or between the active contact AC and the second source/drain pattern SD2.

The active contact AC may be electrically connected through the metal-semiconductor compound layer SC to the source/drain pattern SD1 or SD2. For example, the metal-semiconductor compound layer SC may include at least one selected from titanium silicide, tantalum silicide, tungsten silicide, nickel silicide, and cobalt silicide.

The active contact AC may include a contact conductive pattern FM and a barrier pattern BP that surrounds the contact conductive pattern FM. For example, the contact conductive pattern FM may include at least one selected from aluminum, copper, tungsten, molybdenum, and cobalt. The barrier pattern BP may cover sidewalls and a bottom surface of the contact conductive pattern FM. The barrier pattern BP may include at least one selected from a metal layer and a metal nitride layer. The metal layer may include, for example, at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

The third interlayer dielectric layer 130 may include first conductive structures CST1 formed. The fourth interlayer dielectric layer 140 may include second conductive structures CST2 formed therein. The third interlayer dielectric layer 130 and the fourth interlayer dielectric layer 140 may be similar in some respects to the first dielectric layer ILD1 and the second dielectric layer ILD2 of FIG. 1A, respectively. Each of the first conductive structure CST1 and the second conductive structure CST2 may be similar in some respects to the conductive structure CST of FIG. 1A, the conductive structure CST of FIG. 3, or the conductive structure CST of FIG. 4.

Referring to FIG. 5F, at least a portion of the first conductive structures CST1 may be electrically connected to the active contact AC. The diffusion layer DL of the first conductive structure CST1 may be in contact with the contact conductive pattern FM of the active contact AC. At least portions of the second conductive structures CST2 may be electrically connected to the first conductive structures CST1. The diffusion layer DL of the second conductive structure CST2 may be in contact with the diffusion layer DL of the first conductive structure CST1.

In a semiconductor device according to some example embodiments of the inventive concepts, a conductive structure may include a diffusion layer that surrounds a barrier layer and a capping layer. The presence of the diffusion layer may reduce, minimize or limit electromigration (EM) in the conductive structure. Accordingly, the semiconductor device reliability may be increased.

In a method of fabricating a semiconductor device according to some example embodiments, capping layer may not be present between a barrier layer and a conductive pattern, and thus undulation on a top surface of the conductive pattern, for instance, after a chemical mechanical polishing (CMP) may minimized or reduced. Therefore, the conductive structure may decrease in volume and resistance, and the electrical properties of the semiconductor device may be improved.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor device, comprising:
a conductive structure; and
a dielectric layer that surrounds the conductive structure, wherein the conductive structure includes:
a conductive pattern;
a barrier layer in contact with a sidewall and a lower surface of the conductive pattern;
a capping layer in contact with an upper surface of the conductive pattern; and
a diffusion layer that surrounds the barrier layer and the capping layer,
wherein the barrier layer includes a first conductive layer and a second conductive layer that include different conductive materials from each other,
wherein the capping layer and the second conductive layer include a same conductive material,
wherein the diffusion layer includes manganese (Mn), and
wherein the second conductive layer contacts the conductive pattern, the first conductive layer, and the diffusion layer.

2. The semiconductor device of claim 1, wherein
the barrier layer includes a plurality of second conductive layers, and
the first conductive layer is between second conductive layers that are adjacent to each other.

3. The semiconductor device of claim 1,
wherein the barrier layer includes:
an inner sidewall in contact with the conductive pattern; and
an outer sidewall opposite to the inner sidewall,
wherein the diffusion layer includes:
a contact surface in contact with an upper surface of the capping layer; and
an upper surface opposite to the contact surface, and
wherein a width of the upper surface of the diffusion layer is greater than a diameter of the outer sidewall of the barrier layer.

4. The semiconductor device of claim 3, wherein the barrier layer further includes an upper surface that connects the inner sidewall and the outer sidewall of the barrier layer to each other, and
wherein the diffusion layer completely overlaps the upper surface of the barrier layer.

5. The semiconductor device of claim 1, wherein
the first conductive layer includes TaN, and
the second conductive layer includes cobalt (Co).

6. The semiconductor device of claim 1, wherein a width of the upper surface of the conductive pattern is a same as a width of the capping layer.

7. The semiconductor device of claim 1, wherein a concentration of manganese (Mn) in the diffusion layer is higher than a concentration of manganese (Mn) in the conductive pattern.

8. The semiconductor device of claim 1, wherein the conductive pattern includes:
a first via part; and
a wiring part on the first via part,
wherein the first via part is spaced apart from the capping layer and contacts the barrier layer.

9. The semiconductor device of claim 8, wherein an upper surface of the wiring part contacts a lower surface of the capping layer.

10. The semiconductor device of claim 8, wherein a sidewall of the wiring part contacts the barrier layer.

11. The semiconductor device of claim 8, wherein a width of the capping layer is greater than a width of the first via part.

12. The semiconductor device of claim 8, wherein the conductive pattern further includes a second via part spaced apart from the first via part,
wherein the second via part is spaced apart from the capping layer and contacts the barrier layer.

13. A semiconductor device, comprising:
a conductive structure; and
a dielectric layer that surrounds the conductive structure,
wherein the conductive structure includes:
a conductive pattern;
a barrier layer in contact with a sidewall and a lower surface of the conductive pattern;
a capping layer in contact with an upper surface of the conductive pattern; and
a diffusion layer that surrounds the barrier layer and the capping layer,
wherein the barrier layer includes a plurality of first conductive layers and a plurality of second conductive layers, the first and second conductive layers including different conductive materials from each other,
wherein the capping layer and the second conductive layer include a same conductive material,
wherein the diffusion layer includes manganese (Mn), and
wherein the plurality of first conductive layers and the plurality of second conductive layers are alternately arranged on the sidewall and the lower surface of the conductive pattern.

14. The semiconductor device of claim 13, wherein the plurality of first conductive layers include:
a first lower conductive layer in contact with the lower surface of the conductive pattern; and
a first upper conductive layer in contact with the sidewall of the conductive pattern.

15. The semiconductor device of claim 14, wherein the plurality of second conductive layers include:
a second lower conductive layer in contact with the lower surface of the conductive pattern; and
a second upper conductive layer in contact with the sidewall of the conductive pattern.

16. The semiconductor device of claim 15, wherein each of the first upper conductive layer and the second upper conductive layer has an outer sidewall in contact with the diffusion layer, and
wherein the outer sidewall of the first upper conductive layer is coplanar with the outer sidewall of the second upper conductive layer.

17. The semiconductor device of claim 13, wherein
the plurality of second conductive layers include cobalt (Co), and
a concentration of cobalt (Co) in the plurality of second conductive layers is higher than a concentration of cobalt (Co) in the plurality of first conductive layers.

18. A semiconductor device, comprising:
a conductive structure; and
a dielectric layer that surrounds the conductive structure,
wherein the conductive structure includes:
a conductive pattern;
a barrier layer in contact with a sidewall and a lower surface of the conductive pattern;
a capping layer in contact with an upper surface of the conductive pattern; and
a diffusion layer that surrounds the barrier layer and the capping layer,
wherein the barrier layer includes a first conductive layer and a second conductive layer that include different conductive materials from each other,
wherein the capping layer and the second conductive layer include a same conductive material,
wherein the diffusion layer includes manganese (Mn),
wherein the diffusion layer has:
a first inner sidewall in contact with a sidewall of the capping layer; and
an outer sidewall opposite to the first inner sidewall, and
wherein a distance between the first inner sidewall and the outer sidewall of the diffusion layer is greater than a thickness of the barrier layer.

19. The semiconductor device of claim 18, wherein the diffusion layer further includes:
a second inner sidewall in contact with an outer sidewall of the barrier layer; and
a connection surface in contact with an upper surface of the barrier layer,
wherein the connection surface of the diffusion layer connects the first inner sidewall and the second inner sidewall of the diffusion layer to each other.

20. The semiconductor device of claim 19, wherein the diffusion layer further includes a contact surface in contact with an upper surface of the capping layer,
wherein the first inner sidewall of the diffusion layer connects the contact surface and the connection surface of the diffusion layer to each other.
